(19) United States
(12) Patent Application Publication
(10) Pub. No.: US 2006/0227628 A1
(43) Pub. Date: Oct. 12, 2006

(54) Display driver and display driving method

(76) Inventors: Takuya Eriguchi, Yokosuka (JP); Yasuyuki Kudo, Fujisawa (JP); Akihito Akai, Yokohama (JP); Naoki Takada, Yokohama (JP); Goro Sakamaki, Fuchu (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/299,743

(22) Filed: Dec. 13, 2005

(30) Foreign Application Priority Data
Mar. 24, 2005 (JP) 2005-085170

(51) Int. Cl. G11C 7/06

(52) U.S. Cl. 365/189.07

(57) ABSTRACT

In a display driver, a period D following a period P in one scanning period is divided into periods R, G, and B in which data voltages are applied to data lines R, G, and B, and two output orders of the data voltage such as the period R→the period G→period B and the period B→the period G→period R are switched in each two frames.

### CROSS-REFERENCE TO RELATED APPLICATION

The present application claims priority from Japanese Patent Application No. JP 2005-85170 filed on Mar. 24, 2005, the content of which is hereby incorporated by reference into this application.

### TECHNICAL FIELD OF THE INVENTION

The present invention relates to a display driver for an active matrix display using a TFT (Thin Film Transistor) liquid crystal or the like. More particularly, it relates to a technology effectively applied to a driving method and a drive circuit which can reduce a fluctuation of data voltage held in a data line, in a drive system in which the data voltage is outputted in a time-sharing manner in one horizontal period.

### BACKGROUND OF THE INVENTION

In general, in the active matrix display in which a plurality of scanning lines and a plurality of data lines are arranged in a matrix shape, a scanning voltage showing a selected state is sequentially applied to the scanning line in each one scanning period, and a data voltage corresponding to the display data on the selected scanning line is applied to the data line. In this case, as a method for reducing a circuit scale of the data line drive circuit, a method of driving the data line in a time-sharing manner within one scanning period has been known. In this method, a plurality of data lines are set as one block, a circuit (multiplexer) which outputs the data voltage corresponding to the data lines in one block in a time-sharing manner is provided, a circuit (demultiplexer) which distributes the outputted data voltage is provided, and the data voltage is sequentially applied to the data lines in one block. In accordance with this method, since it is possible to drive a plurality of data lines by one drive circuit, it is possible to achieve a circuit scale saving.

However, in the system mentioned above, since the data line in which the application of the data voltage is completed becomes in a floating state, there is a problem that a holding potential is changed due to the influence of the subsequent data voltage outputs. This is because of the capacity coupling between the adjacent data lines. As a method for improving this, there is an electro-optical device described in Japanese Patent Application Laid-Open Publication No. 2004-191544. This electro-optical device is characterized in that a pre-charge period (hereinafter, referred to as a period P) in which a pre-charge voltage is applied to all the data lines in one block is provided at the time of starting one scanning period, and the pre-charge voltage is an average of the data voltages to be applied. According to this method, a voltage closer to an original data voltage is already applied to the data line in the subsequent time-sharing drive period (hereinafter, referred to as a period D), and a potential fluctuation until reaching the original data voltage is reduced. In the case where the potential fluctuation of the data line is small, the influence to the other data lines which are capacity-coupled thereto is also reduced. Accordingly, the problem mentioned above can be solved, that is, it is possible to reduce the fluctuation of the holding potential of the data line in a floating state.

### SUMMARY OF THE INVENTION

However, in the method described in Japanese Patent Application Laid-Open Publication No. 2004-191544 mentioned above, since it is necessary to newly add a circuit for calculating the average value of the data voltages; there is a problem that a circuit scale is increased. Further, since such a case may occur where a data voltage largely deviated from the average value is applied depending on a display data, there is a problem that a display pattern dependency affects the effect of reducing the holding potential fluctuation.

Accordingly, an object of the present invention is to provide a display driver, which can reduce a holding potential fluctuation of a data line without adding any new circuit and without depending on a display pattern.

As mentioned above, for the reduction of the fluctuation of the holding potential of the data line in the floating state, it is effective to average and reduce the fluctuation amount of the holding potential. That is to say, if the fluctuation in the holding potential can be averaged and reduced, the problem of the fluctuation in the holding potential can be solved. Paying attention to this point, in the display driver of the present invention, the period D following the period P in one scanning period is divided into a period R, a period G, and a period B in which data voltage is applied to the data lines R, G, and B, respectively. The output order of the data voltage in the period D is switched in each two frames between the order of period R→period G→period B and the order of period B→period G→period R, and different output orders of data voltages are set in each of adjacent pixels on the display panel so as to form the checkerboard display pattern. By doing so, the degradation in picture quality can be prevented and the fluctuations in the holding potentials of the data lines R, G, and B can be averaged, so that the fluctuation amount can be reduced to half. Accordingly, the problem of the fluctuation in the holding potential can be solved.

According to the present invention, the fluctuation in the holding potential can be averaged and reduced in all the data lines only by changing the output operation of the data voltages in time-sharing drive. Therefore, it is possible to provide a display driver capable of reducing the fluctuation in the holding potential of the data lines without newly adding any circuit and without depending on the display pattern.

### BRIEF DESCRIPTIONS OF THE DRAWINGS

FIG. 1 is a diagram showing an output method at the time of time-sharing drive as a comparison example to the present invention;

FIG. 2 is a diagram showing an output method at the time of time-sharing drive according to the present invention based on the concept of the present invention;

FIG. 3 is a diagram showing a display pattern (each-one-dot toggle pattern (four frames)) according to the present invention based on the concept of the present invention;

FIG. 4 is a block diagram showing the configuration of a display driver according to a first embodiment of the present invention;

FIG. 5 is a diagram showing the configuration of an MUX(A) of a multiplexer in the display driver according to the first embodiment of the present invention;

FIG. 6 is a diagram showing the configuration of an MUX(B) of a multiplexer in the display driver according to the first embodiment of the present invention;

FIG. 7 is a diagram showing the configuration of a DeMUX(A) of a demultiplexer in the display driver according to the first embodiment of the present invention;

FIG. 8 is a diagram showing the configuration of a DeMUX(B) of a demultiplexer in the display driver according to the first embodiment of the present invention;

FIG. 9 is a timing chart showing the operation timing of a time-sharing drive in a drive circuit of the display driver according to the first embodiment of the present invention;

FIG. 10 is a diagram showing a display pattern (each-two-dots toggle pattern (four frames)) in the display driver according to a second embodiment of the present invention;

FIG. 11 is a timing chart showing the operation timing of a time-sharing drive in a drive circuit of the display driver according to the second embodiment of the present invention;

FIG. 12 is a diagram showing a display pattern (each-one-dot toggle pattern (eight frames)) in the display driver according to a third embodiment of the present invention;

FIG. 13 is a diagram showing a display pattern (each-two-dots toggle pattern (eight frames)) in the display driver according to a fourth embodiment of the present invention;

FIG. 14 is a diagram showing a method of setting instruction in the 16-bit bus mode in the display driver according to a fifth embodiment of the present invention; and

FIG. 15 is a diagram showing a driver output control register in the 16-bit bus mode in the display driver according to the fifth embodiment of the present invention.

### DESCRIPTIONS OF THE PREFERRED EMBODIMENTS

(Concept of the Present Invention)

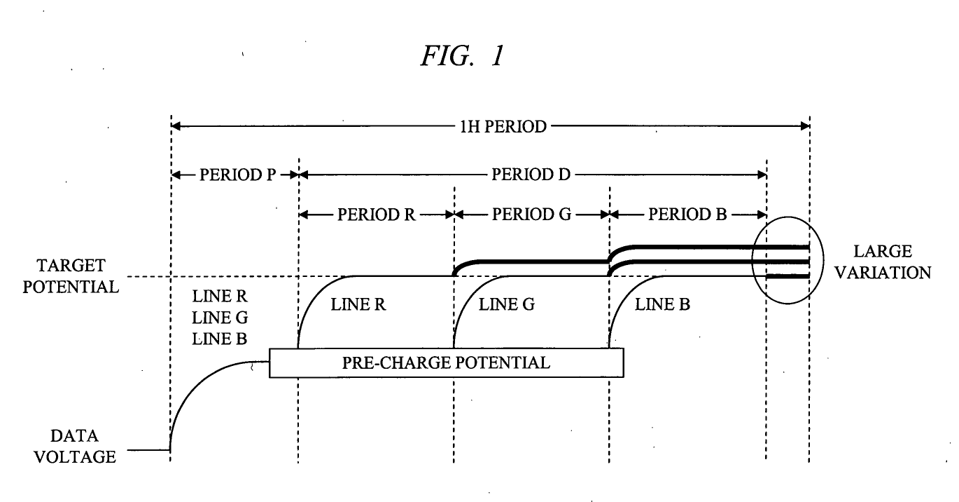

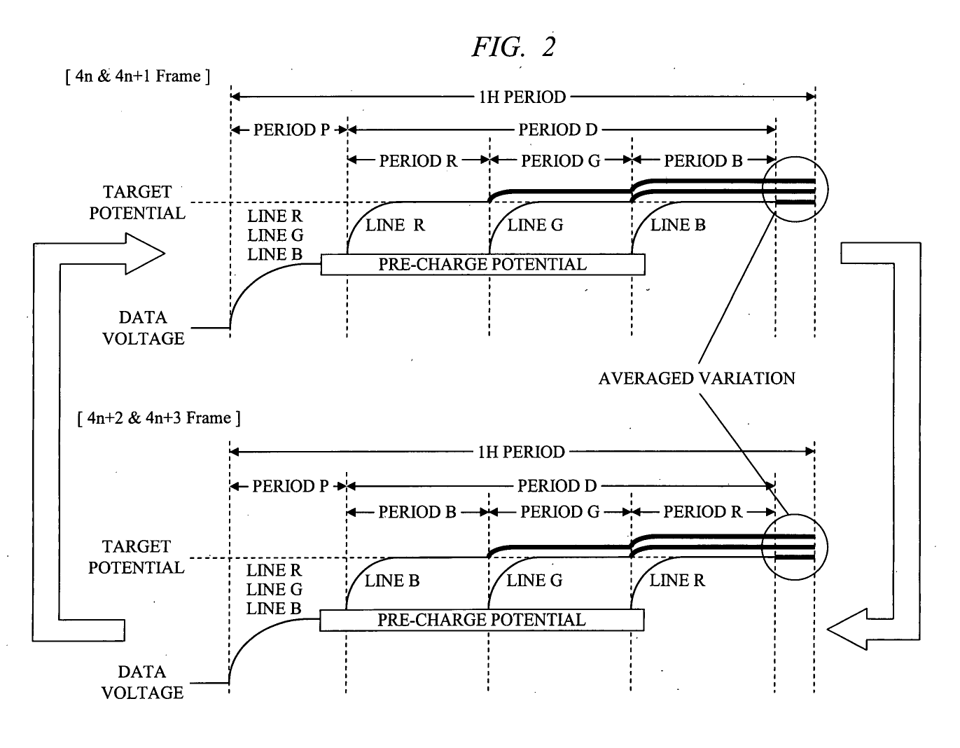

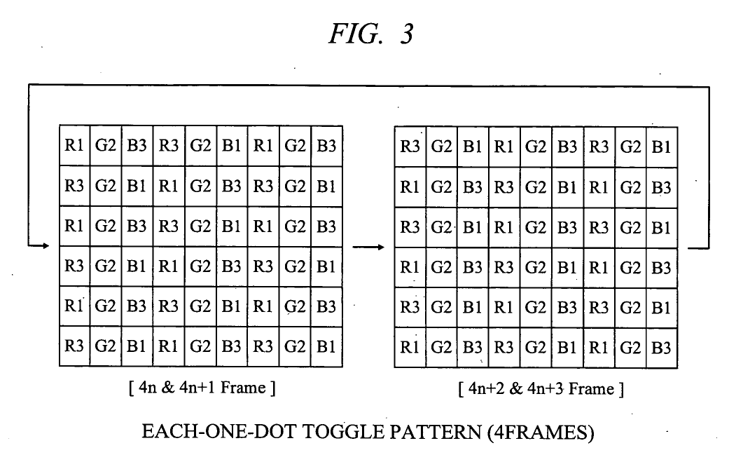

The basic concept of the present invention will be described with reference to FIG. 2 and FIG. 3. The description of FIG. 2 and FIG. 3 is made with reference to FIG. 1 which is a comparison example to FIG. 2 so as to assist the understanding of the features of the present invention.

In FIG. 1 showing a comparison example to the present invention, one example of output method in the time-sharing drive is shown, in which the period P in which a pre-charge voltage is applied to all the data lines in one block is provided at the start of one scanning period (1H period). Note that one block is composed of three data lines corresponding to R (red display), G (green display), and B (blue display). One scanning period is divided into periods P and D in which a data voltage is applied to each data line, and the period D is further divided into three periods such as a period R in which the data voltage is outputted to the line R, a period G in which the data voltage is outputted to the line G, and a period B in which the data voltage is outputted to the line B. When no data voltage is outputted in the periods R, G, and B, a high impedance (hereinafter, referred to as Hi-Z) output is kept.

First, an advantage in the case of providing the period P will be described. For example, when the line R is driven immediately after the beginning of one scanning period, since the lines G and B are put into a Hi-Z output state during this period, the potential applied in the previous scanning period is held. Assuming that the so-called Vcom alternating drive in which the voltage Vcom is alternated in each one scanning period, since the Vcom electrode and the data line are capacity-coupled to each other, the holding voltage of the data line transits in conjunction with the transition of the voltage Vcom, and the holding potential after the transition exceeds the amplitude range of the data voltage in some cases. In other words, in the Vcom alternating drive, since the holding potential of the data line fluctuates in accordance with the alternation of the Vcom, the potential difference from the data voltage which is applied next is extended, and it is expected that the time margin with respect to the settling of the data voltage is reduced. The period P is provided so as to suppress the reduction of the time margin.

Next, the holding potential of each of RGB data lines in the period D will be described below. The holding potential of the line R after the period R fluctuates when data voltages are outputted to the lines G and B. Also, the fluctuation in the holding potential of the line G after the period G is about half of the fluctuation in the holding potential of the line R because it fluctuates only when a data voltage is outputted to the line B. In addition, fluctuation in the holding potential of the line B due to capacity coupling to adjacent data lines does not occur because the data voltage is outputted to the line B at the end of one scanning period. When data voltages are outputted in the order of line R→line G→line B in the manner described above, the fluctuation in the holding potential of each of RGB lines always keeps the relation of R (larger)>G (middle)>B (0), and the variation occurs in the fluctuation in the holding potential. For that reason, in the present invention, the fluctuation in the holding potential on the data lines in a floating state is averaged by switching the order of outputting the data voltage to each of the data lines.

FIG. 2 shows a method of switching the output order of the data voltages to the lines R and B in each two frames at the time of writing to one pixel (hereinafter referred to as toggle method). First, at the frames of 4n and 4n+1, the data voltage is outputted in the order of R→G→B. Next, at the frames of 4n+2 and 4n+3, the data voltage is outputted in the order of B→G→R. By switching the output order of the data voltage to the lines R and B in this manner, fluctuation in the holding potential of the lines R and B repeats “large” and “0” in each two frames, and as a result, the fluctuation in the holding potential of the lines R and B becomes “middle.” Also, since the data voltage is always outputted second to the line G, the fluctuation in the holding potential is kept middle. Thus, by switching the output order of the data voltage to the lines B and R in this manner, the fluctuation in the holding potential of the lines R, G, and B can be averaged. At this point, the fluctuation can be reduced by 50% in comparison to that of the example in FIG. 1. Further, by switching the output order in each two frames, DC components at both of the positive and negative polarities can be removed. Note that the reason why the output order of the data voltage to the line G is fixed is that, since green is a color easily discriminated by human eyes, if the output order of the data voltage to the G line is switched, the difference in luminance due to the change in the fluctuation in the holding potential is perceived as flicker.

Next, display patterns based on the toggle method will be described with reference to FIG. 3. FIG. 3 shows patterns based on the method in which the voltage is applied in different ways to each of adjacent pixels in a panel (hereinafter, referred to as each-one-dot toggle pattern). In FIG. 3, the alphabets RGB denote colors, and numerals denote the order of outputs. At the time of positive polarity in a normally black panel and Vcom alternating drive, since the fluctuation in the holding potential of the data lines to which the data voltage is first outputted is large, luminance is high, and since the potential of the data lines to which the data voltage is third outputted does not fluctuate, luminance is low. In the display screen, when R1 is adjacent to a horizontal line and R3 is adjacent to the next horizontal line in the lines R, a spatial correlation in a screen becomes high (spatial frequency is low), and when the frame frequency is low, the shading and the above-described display patterns repeated on each horizontal line become conspicuous, and as a result, the picture quality is lowered. In contrast, by setting different output orders for each of adjacent pixels, R1 and R3 forms the checkerboard pattern in the lines R, and the spatial correlation in a screen becomes lowest (spatial frequency is high), and as a result, the above-described display pattern becomes invisible even at the low frame frequency.

Hereinafter, embodiments of the present invention to which the concept of the present invention is applied will be described in detail with reference to the accompanying drawings. Note that components having the same function are denoted by the same reference symbols throughout the drawings for describing the embodiment, and the repetitive description thereof will be omitted.

### First Embodiment

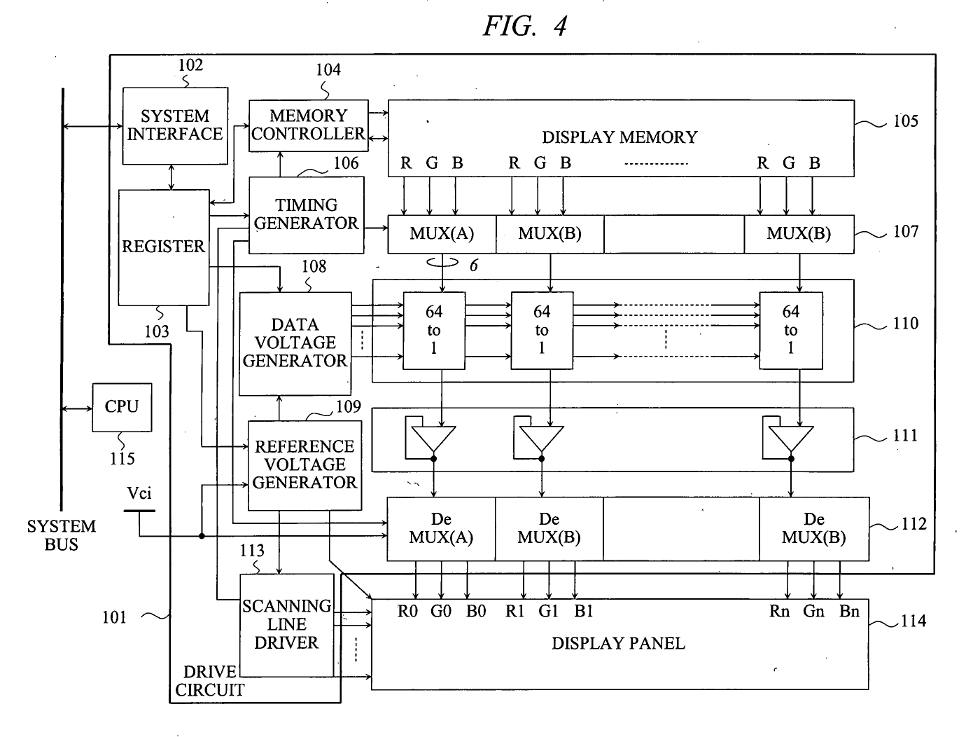

The configuration and operation of the display driver according to a first embodiment of the present invention will be described below with reference to FIG. 4 to FIG. 9.

First, FIG. 4 shows a block configuration of a display driver according to the first embodiment of the present invention. In FIG. 4, a reference numeral 101 denotes a drive circuit, 102 denotes a system interface (IF), 103 denotes a register, 104 denotes a memory controller, 105 denotes a display memory, 106 denotes a timing generator, 107 denotes a multiplexer (MUX), 108 denotes a reference voltage generator, 109 denotes a data voltage generator, 110 denotes a data voltage selector (64 to 1), 111 denotes an operational amplifier (Op-AMP), 112 denotes a demultiplexer (DeMUX), 113 denotes a scanning line driver, 114 denotes a display panel, and 115 denotes a CPU.

The drive circuit 101 is a so-called display memory built-in type controller driver, and it includes achieving means according to the present invention. In this case, the drive circuit 101 according to the present invention is not limited to the display memory built-in type, but can be applied to a type in which a memory is not built. Further, in this embodiment, the number of the data lines in one block is set to three, and they correspond to an R line (red display), a G line (green display) and a B line (blue display). Further, in this embodiment, grayscale information included in the display data is set to 6 bits in each of RGB (64 grayscales).

A configuration and operation of an internal block of the drive circuit 101 will be described below.

The system interface 102 receives a display data and an instruction outputted by the CPU 115 and outputs them to the register 103. In this case, the instruction indicates the information for determining an internal operation of the drive circuit 101, and it includes various parameters such as a frame frequency, the number of drive lines, a driving voltage and the like. Further, the information relating to the output order to each of the data lines RGB which is a feature of the present invention is also included in the instruction.

The register 103 is a block which stores the data of the instruction and outputs it to each of the blocks. For example, the instruction relating to the frame frequency, the number of the drive lines and the data voltage switching timing is outputted to the timing generator 106, and the instruction relating to the driving voltage is outputted to the reference voltage generator 109. Note that the display data is temporarily stored in the register 103 and then is outputted to the memory controller 104 together with the instruction indicating a display position.

The memory controller 104 is a block which executes a write and read operations of the display memory 105. First, at the time of the write operation, a signal which selects an address of the display memory 105 is outputted on the basis of the instruction of the display position transferred from the register 103. At the same time, the display data is transferred to the display memory 105. By this operation, it is possible to write the display data in a predetermined address of the display memory 105. On the other hand, at the time of the read operation, an operation of sequentially selecting predetermined word lines in a word line group in the display memory 105 one by one is repeated. By this operation, it is possible to read the display data on the selected word line via a bit line all at once. Note that the settings of a range of the word line to be read, a period of one selection (equivalent to one scanning period), a repeating period of the selecting operation (equivalent to one frame period) and the like are indicated by the instruction.

The display memory 105 has a word line and a bit line corresponding to a scanning line and a data line of the display panel 114, and it executes the write operation and the read operation of the display data mentioned above. Note that the read display data is outputted to the multiplexer 107.

The timing generator 106 generates and outputs a signal group indicating one scanning period and one frame period by itself on the basis of a reference clock generated by a built-in oscillator, and it also outputs PE, SRA, SRB, SG, SBA and SBB signals indicating output timings in the period P and the period D which are the feature of the present invention.

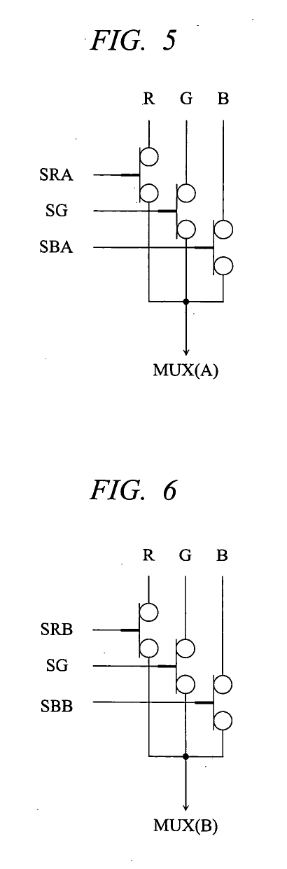

In the configuration of the multiplexer 107, switching circuits MUX(A) and MUX(B) shown in FIG. 5 and FIG. 6 respectively are arranged for each block so as to multiplex the display data outputted from the display memory 105. The switching circuit MUX(A) selects and outputs a data R when the signal SRA is active (“high” level in this embodiment), a data G when the signal SG is active, and a data B when the signal SBA is active. The switching circuit MUX(B) selects and outputs a data R when the signal SRB is active, a data G when the signal SG is active, and a data B when the signal SBB is active.

The reference voltage generator 109 is a block which generates a voltage level required in the drive circuit 101 from an input power supply voltage Vci. Note that the generation of the voltage level can be achieved by applying a charge pump circuit or the like.

The data voltage generator 108 divides a voltage inputted from the reference voltage generator 109 to generate a 64-level data voltage, and then outputs it to the data voltage selector 110.

The data voltage selector 110 selects one level from the 64-level data voltage in accordance with a value of the display data outputted by the multiplexer 107 and then outputs the selected one as the data voltage.

The operation amplifier 111 is a buffer for impedance conversion of the output of the data voltage selector 110, and is composed of voltage follower circuits.

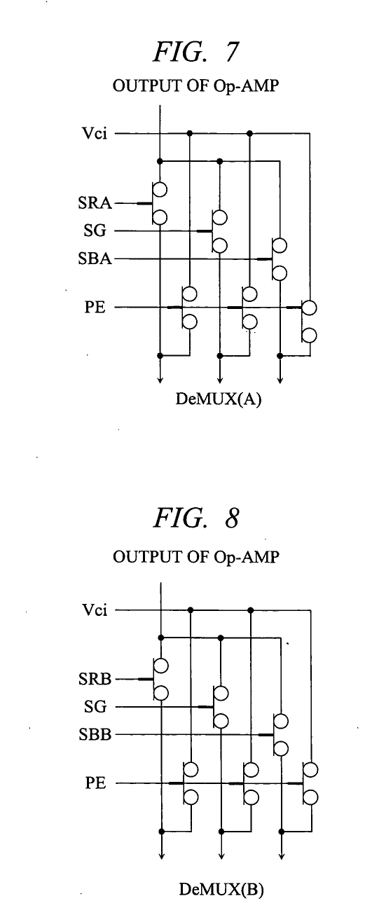

In the configuration of the demultiplexer 112, switching circuits of DeMUX(A) and DeMUX (B) shown in FIG. 7 and FIG. 8 respectively are arranged for each block so as to demultiplex the data voltage outputted by the operational amplifier 111 and to output it to the data lines. The DeMUX(A) outputs a data voltage to the line R when the signal SRA is active (“high” level in this embodiment), to the line G when the signal SG is active, and to the line B when the signal SBA is active, respectively. Also, the DeMUX(B) outputs the data voltage to the line R when the signal SRB is active, to the line G when the signal SG is active, and to the line B when the signal SBB is active, respectively. Further, both the DeMUX(A) and DeMUX(B) pre-charge a fixed potential on the data lines R, G, and B when the signal PE is active. Note that, as the fixed potential, the power supply voltage Vci which is within the amplitude range of the data voltage and has a low output impedance is selected.

The scanning line driver 113 is a block for sequentially outputting a scanning voltage (“high” level in this embodiment) which sets a pixel to a selected state in synchronous with one scanning period to a scanning line of the display panel 114 mentioned later. In this case, a timing at which the “high” level is outputted to a first scanning line is synchronized with a timing at which a first word line in the display memory 105 is read. Further, a switching timing of the line sequential output is slightly earlier than a start of one scanning period. This time difference is a so-called hold time, and it is necessary for determining a writing voltage to the pixel in the display panel 114.

The display panel 114 is a flat panel of a so-called active matrix type, in which transistors for switching are disposed in each of the pixels positioned so as to corresponding to the intersection points between the data lines and the scanning lines. A source terminal of the transistor is connected to an output of the demultiplexer 112 via the data line, and a gate terminal thereof is connected to an output of the scanning line driver 113 via the scanning line. Further, a drain terminal of the transistor is connected to a display element. Note that a common electrode is connected to an opposite side of the display element, and a voltage Vcom is outputted to the common electrode from the reference voltage generator 109. Accordingly, in the scanning line in a selected state, a difference between the data voltage and the voltage Vcom becomes an applied voltage to the display element. Note that, although a liquid crystal, an organic EL and the like are typical of the display element, other elements can be employed as long as a display luminance can be controlled by the voltage.

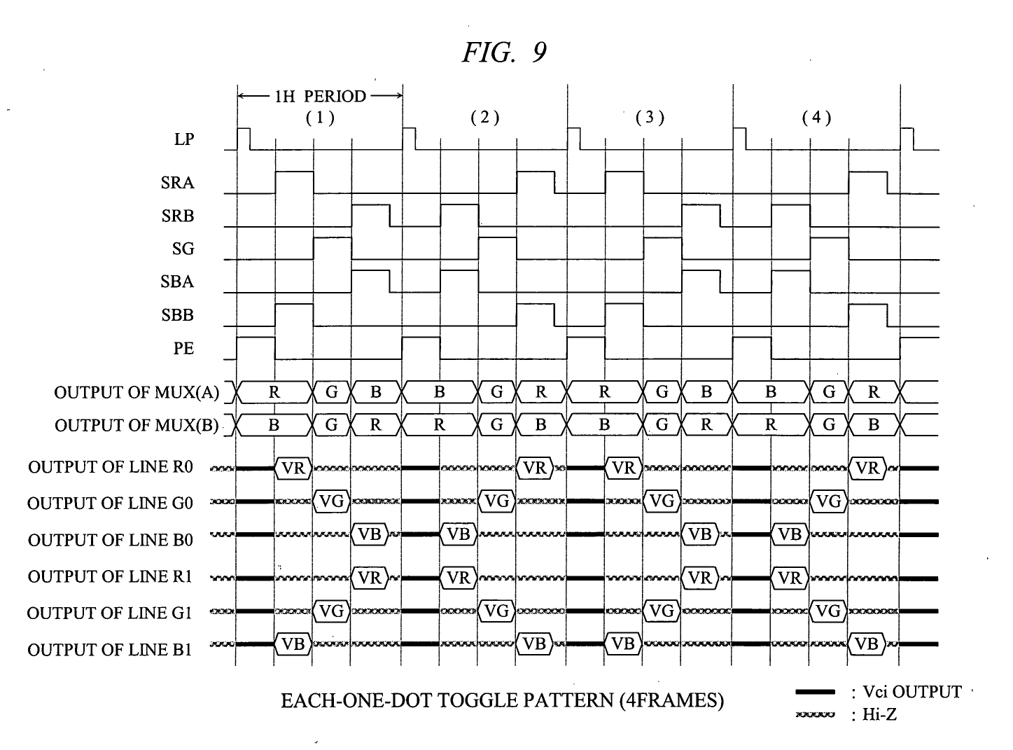

Next, the operation timing for time-sharing drive in the drive circuit 101 will be described with reference to FIG. 9. First, the MUX(A) in the multiplexer 107 operates in conjunction with “high” level of the signals SRA, SG, and SBA and outputs the display data in a time-sharing manner in the order of R→G→B in the periods (1) and (3) and in the order of B→G→R in the periods (2) and (4). On the other hand, the MUX(B) in the multiplexer 107 operates in conjunction with “high” level of the signals SRB, SG, and SBB and outputs the display data in a time-sharing manner in the order of B→G→R in the periods (1) and (3) and in the order of R→G→B in the periods (2) and (4).

Next, the operation timing of the demultiplexer 112 will be described. DeMUX(A) and DeMUX(B) in the demultiplexer 112 operate in conjunction with “high” level of the signal PE and output the voltage Vci concurrently to the data lines R, G, and B. Also, DeMUX(A) in the demultiplexer 112 operates in conjunction with the output of the MUX(A) in the multiplexer 107 and outputs the data voltages VR, VG, and VB in the order of the lines R→G→B in the period D of (1) and (3) and in the order of the lines B→G→R in the period D of (2) and (4). Also, DeMUX(B) in the demultiplexer 112 operates in conjunction with the output of the MUX(B) in the multiplexer 107 and outputs the data voltages VR, VG, and VB in the order of the lines B→G→R in the period D of (1) and (3) and in the order of the lines R→G→B in the period D of (2) and (4).

After the two frames of the above-mentioned operations, the operation timings of SRA and SRB are switched in the following two frames, and further the operation timings of SBA and SBB are switched. By doing so, as mentioned above, R1 (B1) and R3 (B3) can be displayed as a checkerboard pattern in each two frames as shown in FIG. 3. Note that, as described above, the length of each period in the toggle method can be changed by the instruction from the CPU 115, and it is preferable that it is set optimally in accordance with the load of the display panel 114 to be driven. Further, SRA and SBB can be made in common, alternatively, SRB and SBA can be made in common.

As described above, by switching the order of outputting the data voltage to the lines R and B in each two frames to form the checkerboard display pattern, it is possible to average the variation of fluctuation in the holding potential of the data lines in a floating state without degrading the picture quality, which makes it possible to reduce the fluctuation in the holding potential to half in comparison with the conventional one. Also, the above-mentioned operation can be realized only by changing the timing of the signal from the timing generator 106, and it is unnecessary to add any new circuits. Therefore, the display driver of the present invention can achieve the object of the present invention, that is, the reduction of the fluctuation in the holding potential of the data lines without adding new circuits and depending on display pattern.

Note that, in FIG. 9, at the end of one scanning period, a period in which no output is given to any data lines is provided. This is a period for securing the hold time mentioned in the description of the operation of the scanning line driver 113.

Further, in this embodiment, a pre-charge voltage level is set to the voltage Vci, but it is not limited to this, and other voltages can be used instead.

Also, with respect to the output order, the object and effect of the present invention can be achieved if the output order to R, G, and B is reversed at least in the pixels in the line direction. This means that it is not essential to reverse the output order in the column direction and in the frame period.

Further, it is preferable that output orders are R→G→B and B→G→R when pixels are arranged in the order of R, G, and B. When pixels are arranged in the order of R, B, and G, however, it is preferable that output orders are R→B→G and G→B→R.

### Second Embodiment

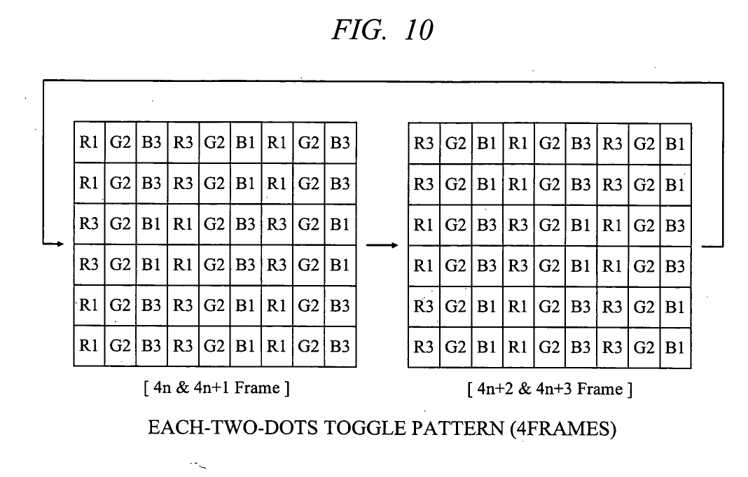

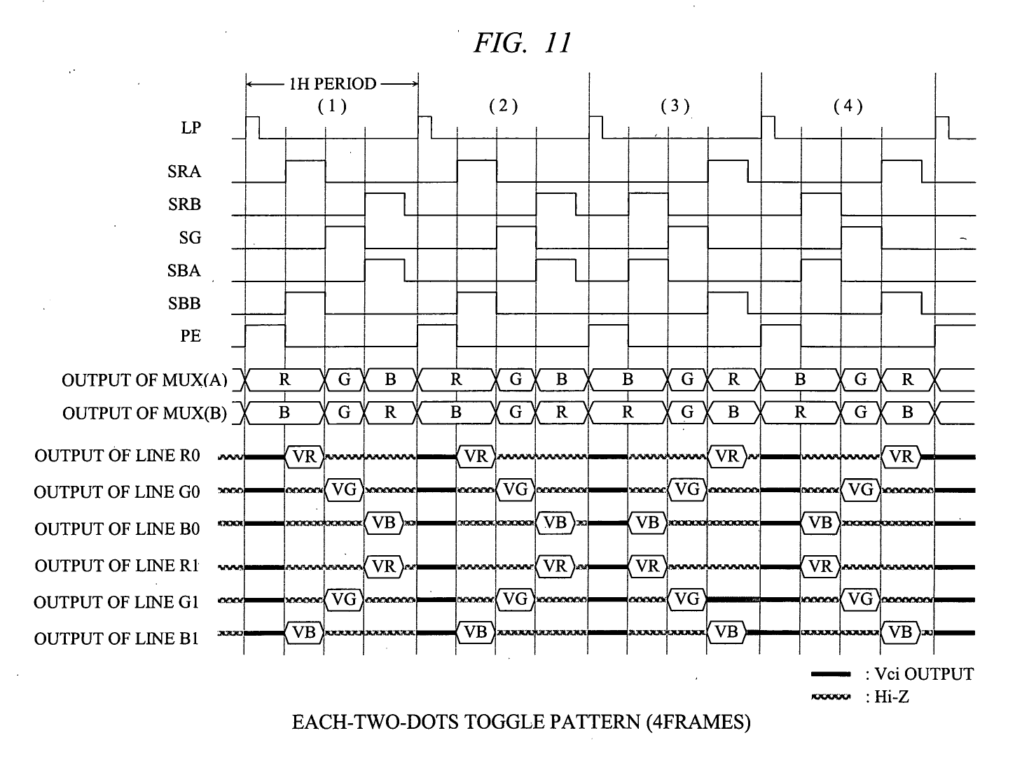

Next, a display driver according to a second embodiment of the present invention will be described below with reference to FIG. 10 and FIG. 11. FIG. 10 shows a pattern displayed by outputting the voltages in the different orders to each two pixels adjacent in the vertical direction (hereinafter referred to as “each-two-dots toggle pattern”). Note that the display driver of this embodiment has the same configuration as that of the first embodiment of the present invention shown in FIG. 4 to FIG. 8.

For example, in the FRC (frame rate control) in which the number of grayscales is increased in a pseudo way by producing intermediate colors by displaying two colors with difference in luminance while switching them in each frame, a checkerboard pattern is used as a display pattern in order to increase the spatial frequency similar to the first embodiment. In this case, in the first embodiment of the present invention, due to the synchronization with the FRC, difference in brightness probably occurs in accordance with the frames, that is, it is bright in some frame but it is dark in the following frame. This may cause degradation in picture quality called surface flicker. Therefore, the above-mentioned each-two-dots toggle pattern is used so as to prevent the interference with FRC. Although the spatial frequency is slightly reduced than that in the first embodiment of the present invention, it little influences the picture quality.

Next, the operation timing in the second embodiment will be described below with reference to FIG. 11. First, the MUX(A) in the multiplexer 107 operates in conjunction with “high” level of the signals SRA, SG, and SBA and outputs the display data in a time-sharing manner in the order of R→G→B in the periods (1) and (2) and in the order of B→G→R in the periods (3) and (4). On the other hand, the MUX(B) in the multiplexer 107 operates in conjunction with “high” level of the signals SRB, SG, and SBB and outputs the display data in a time-sharing manner in the order of B→G→R in the periods (1) and (2) and in the order of R→G→B in the periods (3) and (4).

Next, the operation timing of the demultiplexer 112 will be described. DeMUX(A) and DeMUX(B) in the demultiplexer 112 operate in conjunction with “high” level of the signal PE and output the voltage Vci concurrently to the data lines R, G, and B. Also, DeMUX(A) in the demultiplexer 112 operates in conjunction with the output of the MUX(A) in the multiplexer 107 and outputs the data voltages VR, VG, and VB in the order of the lines R→G→B in the period D of (1) and (2), and in the order of the lines B→G→R in the period D of (3) and (4). Further, DeMUX(B) in the demultiplexer 112 operates in conjunction with the output of the MUX(B) in the multiplexer 107 and outputs the data voltages VR, VG, and VB in the order of the lines B→G→R in the period D of (1) and (2) and in the order of the lines R→G→B in the period D of the periods (3) and (4).

After the two frames of the above-mentioned operations, the operation timings of SRA and SRB are switched in the following two frames, and further the operation timings of SBA and SBB are switched. By doing so, as mentioned above, R1 (B1) and R3 (B3) can be displayed as a checkerboard pattern of each two pixels arranged in a vertical direction in each two frames as shown in FIG. 10.

As a result, the display driver in the second embodiment of the present invention has the feature that different output orders of data voltages are set for each two adjacent pixels arranged in a vertical direction, in addition to the feature of the first embodiment of the present invention. This prevents the interference with that which displays a checkerboard pattern such as the FRC, and the degradation in picture quality can be prevented.

Note that a checkerboard pattern of each two pixels arranged in the vertical direction is used in this embodiment, but the pattern is not limited to this. Instead, other display patterns may be used as long as they do not interfere with the display pattern of the above-mentioned FRC and do not influence picture quality.

### Third Embodiment

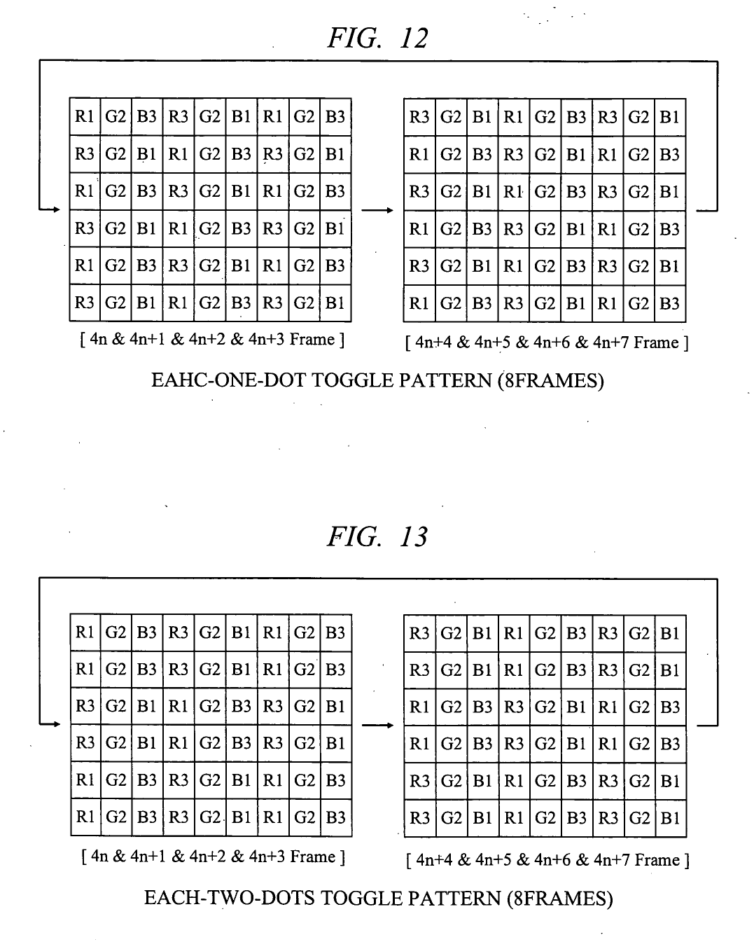

Next, a display driver according to a third embodiment of the present invention will be described below with reference to FIG. 12. FIG. 12 shows a pattern displayed by switching the each-one-dot toggle pattern in each four frames.

For example, in the above-mentioned FRC, display patterns may be switched in each two frames so as to remove the DC current in both of the active and positive polarities. For this reason, in the toggle method shown in the first embodiment, due to the synchronization with the FRC, DC components probably remain, and as a result, the degradation in a liquid crystal element may occur. Thus, the display pattern is switched in each four frames so as to prevent the interference with that in which display patterns are switched in each two frames such as both of the positive and negative polarities and the FRC.

Note that, with respect to the operation timing, the operation timing of SRA and SRB and that of SBA and SBB shown in the first embodiment of the present invention are switched in each four frames. By doing so, the R1 (B1) and R3 (B3) can be displayed as a checkerboard pattern in each four frames.

The display driver in the third embodiment of the present invention described above has the feature that display pattern is switched in each four frames, in addition to the feature of the first embodiment of the present invention. Therefore, the interference with that in which display patterns are switched in each two frames such as the FRC can be removed and the degradation in a liquid crystal element can be prevented.

Note that, in this embodiment, the display pattern is switched in each four frames, but may be switched in each multiples of four frames as long as the picture quality is not degraded.

### Fourth Embodiment

Next, a display driver according to a fourth embodiment of the present invention will be described below with reference to FIG. 13. FIG. 13 shows a pattern displayed by switching the each-two-dots toggle pattern in each four frames.

For example, in the above-mentioned FRC, display patterns may be switched in each two frames so as to remove the DC current in both of the active and positive polarities. Also, the display pattern may have the checkerboard pattern similar to the first embodiment of the present invention. For that reason, in the toggle method shown in the second embodiment of the present invention, due to the synchronization with the FRC, DC components remain, and the degradation in a liquid crystal element may occur. Thus, the display pattern is switched in each four frames so as to prevent the interference with that in which checkerboard patterns are displayed in each two frames such as both of the positive and negative polarities and the FRC.

With respect to the operation timing, the operation timing of SRA and SRB and that of SBA and SBB shown in the second embodiment of the present invention are switched in each four frames. By doing so, the R1 (B1) and R3 (B3) can be displayed as the checkerboard pattern of each two pixels arranged in the vertical direction.

The display driver in the fourth embodiment of the present invention described above has the feature that a checkerboard pattern of each two pixels arranged in the vertical direction is displayed in each four frames, in addition to the feature of the second embodiment of the present invention. Therefore, it is possible to eliminate the interference with that in which a checkerboard pattern is displayed in each two frames such as the above-mentioned FRC, and it is possible to prevent the degradation of a liquid crystal element.

Note that, in this embodiment, the display pattern is switched in each four frames, but the pattern can be switched in multiples of four frames as long as the picture quality is not degraded.

### Fifth Embodiment

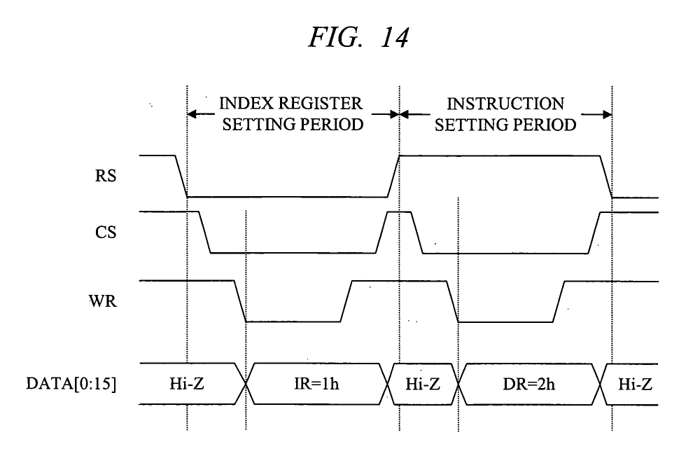

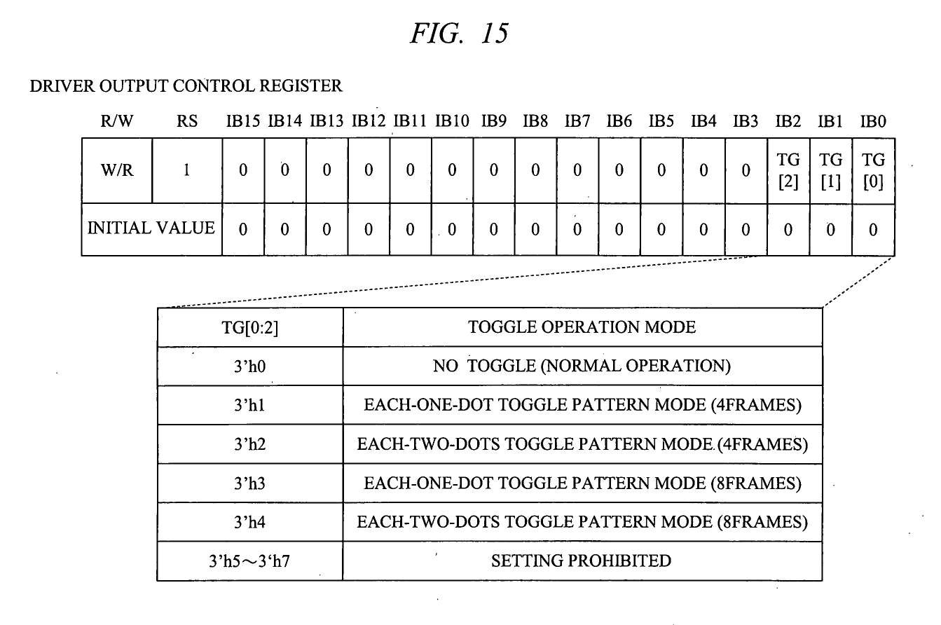

Next, a fifth embodiment of the present invention will be described below with reference to FIG. 14 and FIG. 15. FIG. 14 and FIG. 15 show one example of a method of setting the toggle modes described in the first to four embodiments by means of instructions. More specifically, the first to fourth embodiments can be selectively changed by various mode values set to the internal register from an external CPU.

FIG. 14 shows a method of setting instructions in the 16-bit bus mode. First, the CPU 115 sets a register selection signal RS to a “low” level. It also sets a write enable signal WR and chip selection signal CS to a “low” level and at the same time outputs an index register (IR) to the DATA line. The IR mentioned here is an address value of each control register (group of registers which incorporate the information for determining the internal operations of the drive circuit 101 for each of operation contents). The system interface 102 in the drive circuit 101 stores an IR value in synchronization with the fall time of WR.

Next, the CPU 115 sets the register selection signal RS to a “high” level. It also sets the write enable signal WR and chip selection signal CS to a “low” level and at the same time outputs a data register (DR) value to the DATA line. The DR mentioned here is the data of the control register. The system interface 102 in the drive circuit 101 stores DR value in synchronization with the fall time of WR, and writes the DR value in an address in the register 103 indicated by the IR value stored previously. On the other hand, the register 103 outputs the written instruction data to each block. In the case of the data of a driver output control register, the data written in IR=1 h is outputted to the timing generator 106, and the timing generator 106 then outputs control signals (PE, SRA, SRB, SG, SBA, and SBB) of the MUX(A) and MUX(B) and DeMUX(A) and DeMUX(B) in accordance with the inputted data.

Next, a data group in the driver output control register will be described. FIG. 15 shows the driver output control register in the 16-bit mode. Each toggle mode is selected at the TG [0:2] corresponding to lower three bits out of the 16-bit data. When TG [0:2]=3′h0, a mode for outputting data to each data line in the order of R→G→B as usual without using toggle patterns is selected. When TG [0:2]=3′h1, the mode of each-one-dot toggle pattern (four frames) is selected. When TG [0:2]=3′h2, the mode of each-two-dots toggle pattern (four frames) is selected. When TG [0:2]=3′h3, the mode of each-one-dot toggle pattern (eight frames) is selected. When TG [0:2]=3′h4, the mode of each-two-dots toggle pattern (eight frames) is selected. TG [0:2]=3′h5 to 3′h7 are prohibited to be set, and the initial value 0 is inputted. As described above, each toggle mode can be set by the 3-bit data of TG [0:2].

In the display driver in the fifth embodiment of the present invention mentioned above, it is possible to select an optimum toggle mode in accordance with the various types of panels and frame frequencies by setting various types of output modes of drivers by means of instructions.

The data bus width is 16 bits in this embodiment. However, it is needless to say that the bus width is not limited to this. Also, although the instructions are set by using RS, WR, and CS, the setting of the instructions is not limited to this, but it can be set by using other signals. Further, the driver output control register is 16 bits, but it is not limited to 16 bits. In addition, although a toggle mode is set by lower three bits of the driver output control register, but it is not limited to these, but any bits in the register can be used.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, in all embodiments of the present invention, the number of data lines in one block is three, but it is not limited to this, and it may be N (N is an integer of two or more).

Also, the grayscale information of the display data is six bits for each of R, G, and B (=64 grayscales), but it is not limited to this, eight bits and ten bits can be also used.

Further, in this embodiment, the drive circuit is provided with such components as the data voltage selector, operational amplifier, and demultiplexer, but the drive circuit is not limited to this configuration, and they can be provided in the display panel 114.

Further, the switching of the operations of the first to fourth embodiments of the present invention by means of the instruction from the CPU or the like can be easily realized, and the switching to time-sharing drive method in which the pre-charge is not executed is also possible.

Still further, the description of the embodiments of the present invention has been made on the premise that information such as the drive timing or the like is stored in the register. However, the configuration is not limited to this, but a terminal setting may be employed.

The present invention relates to a display driver for an active matrix display using a TFT liquid crystal or the like. More particularly, it relates to a technology effectively applied to a driving method and a drive circuit which can reduce a fluctuation of data voltage held in a data line, in a drive system in which the data voltage is outputted in a time-sharing manner in one horizontal period. The present invention can be applied particularly to a high picture-quality and low-cost display driver in which time-sharing drive is employed.

What is claimed is:

1. A display driver which applies a scanning voltage for setting a pixel into a selected state to a scanning line of a display panel in each one scanning period and applies a data voltage corresponding to a display data to a data line of said display panel, said display driver comprising:
a circuit for applying the date voltage in a time-sharing manner to a data line group having a plurality of data lines as one block in said one scanning period,
wherein said one scanning period has a first, second, and third periods in which the data voltage is applied in a time-sharing manner to said data line group, and
two types of orders such as the first period→the second period→the third period and the third period→the second period→first period are switched in each fixed period.

2. The display driver according to claim 1,
wherein said two types of orders are different in each of adjacent pixels on said display panel.

3. The display driver according to claim 1,
wherein said two types of orders are different in each two pixels adjacent in a vertical direction on said display panel.

4. The display driver according to claim 1,
wherein said fixed period in which said two types of orders are switched is 2N (N is an integer of one or more) frame period.

5. The display driver according to claim 1,
wherein said fixed period in which said two types of orders are switched is a two-frame period or a four-frame period.

6. The display driver according to claim 1,
wherein said one scanning period further has a pre-charge period prior to the period when the data voltage is applied in a time-sharing manner to said data line group,
said circuit applies a pre-charge voltage to said data line group in said pre-charge period,
said pre-charge voltage has one level, and
the level of said pre-charge voltage is within a range between a maximum level and a minimum level of the data voltage.

7. The display driver according to claim 6,
wherein said two types of orders are different in each of adjacent pixels on said display panel.

8. The display driver according to claim 6,
wherein said two types of orders are different in each two pixels adjacent in a vertical direction on said display panel.

9. The display driver according to claim 6,
wherein said fixed period in which said two types of orders are switched is 2N (N is an integer of one or more) frame period.

10. The display driver according to claim 6,
wherein said fixed period in which said two types of orders are switched is a two-frame period or a four-frame period.

11. The display driver according to claim 1,
wherein data lines constituting said one block are three lines corresponding to red display, green display, and blue display, and
said circuit arbitrarily applies data voltages corresponding to said red display, said green display, and said blue display in each of said first, second, and third periods, respectively.

12. The display driver according to claim 11,
wherein said first period is a period in which said data voltage corresponding to the red display is applied,
said second period is a period in which said data voltage corresponding to the green display is applied, and
said third period is a period in which said data voltage corresponding to the blue display is applied.

13. The display driver according to claim 1 further comprising: a register for setting various modes, in which data voltage is applied in a time-sharing manner to a data line group constituting said one block, from an external processing unit.

14. The display driver according to claim 1,
wherein said circuit applies data voltage to a first data line connected to a first pixel of a red, green, and blue pixels in said first period, applies data voltage to a second data line connected to a second pixel of the red, green, and blue pixels in said second period, and applies data voltage to a third data line connected to a third pixel of the red, green, and blue pixels in said third period.

15. The display driver according to claim 14,
wherein said second pixel is the green pixel.

16. The display driver according to claim 14,
wherein said one scanning period has a pre-charge period before said first period, and
said circuit applies a common pre-charge voltage to said first, second, and third data lines in said pre-charge period.

17. A display driving method which applies a scanning voltage for setting a pixel to a selected state to a scanning line of a display panel in each one scanning period and applies a data voltage corresponding to a display data to a data line of said display panel, in which data voltage is applied in a time-sharing manner to a data line group having a plurality of data lines as one block in each of the first, second, and third periods included in said one scanning period,
wherein two types of orders such as the first period→the second period→the third period and the third period→the second period→first period are switched in each fixed period.
